(19) United States
(12) Patent Application Publication
(10) Pub. No.: US 2023/0403936 A1
(43) Pub. Date: Dec. 14, 2023

(54) DEVICE FOR DETECTING LOW-PRESSURE AND MANUFACTURING METHOD

(71) Applicant: Korea Advanced Institute of Science and Technology, Daejeon (KR)

(72) Inventors: Young-Ho Cho, Daejeon (KR); Mookyum Kim, Daejeon (KR)

(21) Appl. No.: 18/155,249

(22) Filed: Jan. 17, 2023

(30) Foreign Application Priority Data
Jun. 14, 2022 (KR) 10-2022-0072251

(51) Int. Cl. H10N 30/092; G01L 1/16; H10N 30/85; H10N 30/87; H10N 30/30; H10N 30/06

(52) U.S. Cl. CPC H10N 30/092; G01L 1/16; H10N 30/852; H10N 30/877; H10N 30/302; H10N 30/06

(57) ABSTRACT

Provided are a device for detecting low-pressure that includes electrodes positioned on a surface of a porous piezoelectric composite layer in which a piezoelectric nanoparticle and a pore are uniformly distributed, and a manufacturing method thereof.

### CROSS-REFERENCE TO RELATED APPLICATIONS

This application claims priority under 35 U.S.C. § 119 to Korean Patent Application No. 10-2022-0072251, filed on Jun. 14, 2022, in the Korean Intellectual Property Office, the disclosure of which is incorporated herein by reference in its entirety.

### TECHNICAL FIELD

The following disclosure relates to a device for detecting low-pressure and a manufacturing method thereof. More particularly, the following disclosure relates to a device for detecting low-pressure that includes electrodes positioned on a surface of a porous piezoelectric composite layer in which a piezoelectric nanoparticle and a pore are uniformly distributed, and a manufacturing method thereof.

### BACKGROUND

A piezoelectric type detection device may operate using mechanical deformation or movement as its energy source, and may thus detect pressure without external power supply. In particular, a piezoelectric type detection device that mixes a piezoelectric nanoparticle and a polymer may be flexibly manufactured in various shapes (size, thickness, internal structure, device structure, or the like) by ultra-fine processing technology.

A conventional pressure detection device may have increased dispersibility of the piezoelectric nanoparticles by mixing a carbon nanomaterial in a process of mixing the piezoelectric nanoparticle in a piezoelectric composite layer to thus increase internal viscosity of a matrix. However, the conventional pressure detection device may have a limit to controlling formation of clusters (of 20 to 100 μm) aggregated by attraction between the particles.

In addition, in most of conventional technologies, the piezoelectric composite layer may have a non-porous structure to thus have low fluid permeability, have lower uniformity of pores because the pores are formed by mixing and then evaporating liquid solvents, and have difficulty in being formed as a thin flexible film because the layer is manufactured in a mold (>1 mm) by using a casting process.

Furthermore, when electrodes are directly deposited on the piezoelectric composite layer, cracks/wrinkles may occur due to a difference in thermal expansion coefficients of materials. Conventionally, the electrodes have been manufactured by attaching separately prepared electrode layers to a surface of the piezoelectric composite layer. In this case, it is difficult to form a thin film electrode layer of 10 μm or less.

### RELATED ART DOCUMENT

### Patent Document

(Patent Document 1) Korean Patent No. 10-2339058 (registered on Dec. 9, 2021)

### SUMMARY

Embodiments of the present disclosure are directed to providing a device for detecting low-pressure that has increased dispersibility of piezoelectric nanoparticles by preventing the aggregation and precipitation of the particles by performing silane treatment on the piezoelectric nanoparticle and mixing a nonionic surfactant in a matrix in a process of manufacturing a piezoelectric composite layer, and a manufacturing method thereof.

Embodiments of the present disclosure are directed to providing technology for manufacturing a thin porous piezoelectric composite layer having improved moisture permeability by forming a solid precipitation mixture including a solidified precipitated particle in a polymer, and selectively dissolving the solidified precipitated particle by using a liquid solvent to thus produce a structure having a pore in a spin coating process.

Embodiments of the present disclosure are directed to providing technology for manufacturing a thin film electrode having high adhesion and no cracks/wrinkles by sequentially performing the silane treatment and plasma treatment on a surface of the porous piezoelectric composite layer.

In one general aspect, a manufacturing method of the device for detecting low-pressure includes: a first operation of obtaining a silane-treated piezoelectric nanoparticle by mixing a piezoelectric nanoparticle and a silane coupling agent hydrolyzed by a liquid solvent and performing silane treatment thereon; a second operation of obtaining a liquid precipitation mixture solution by mixing a precipitated particle solute and a liquid solvent with a polymer; a third operation of obtaining a solid precipitation mixture in which a solidified precipitated particle is mixed with the polymer by vaporizing the liquid solvent by heating the liquid precipitation mixture solution of the second operation; a fourth operation of obtaining a polymer mixture by mixing a nonionic surfactant with the solid precipitation mixture of the third operation; a fifth operation of obtaining a cured piezoelectric composite layer by mixing the silane-treated piezoelectric nanoparticle of the first operation with the polymer mixture of the fourth operation and curing the same through heat treatment; a sixth operation of obtaining a porous piezoelectric composite layer by removing the solidified precipitated particle from the cured piezoelectric composite layer of the fifth operation by using the liquid solvent; a seventh operation of forming a coating layer by sequentially performing silane treatment and plasma treatment on a surface of the porous piezoelectric composite layer of the sixth operation, and manufacturing a first electrode and a second electrode on the coating layer; and an eighth operation of activating a piezoelectric property by applying a direct current electric field to the first electrode and the second electrode of the seventh operation.

The piezoelectric nanoparticle of the first operation may include one or more of lead zirconate titanate (PZT), barium titanate (BaTiO₃), lead titanate (PbTiO₃), titanium dioxide (TiO₂), strontium titanate (SrTiO₃), and zirconium dioxide (ZrO₂), each of which has a perovskite structure.

The liquid solvent of the first, second, third or sixth operation may include one or more of water, ethanol, methanol, acetone, and toluene.

The silane coupling agent of the first operation may include one or more of 3-glycidoxypropyltrimethoxysilane (GPTMS), 3-mercaptopropyltrimethoxysilane (MPTMS), 3-aminopropyltriethoxysilane (APTES), and bis3-triethoxysilylpropyltetrasulfide (TESPT).

A method of the silane treatment of the first operation may include one or more of ultrasonic vibration, agitation, soaking, and shaking.

The polymer of the second operation may include one or more of polydimethylsiloane (PDMS), polymethylmethacrylate (PMMA), negative epoxy based photoresist (SU-8), and polyurethane leather (PU).

The precipitated particle solute of the second operation may include one or more of citric acid, sugar, salt, and baking soda.

The nonionic surfactant of the fourth operation may include one or more of triton, nonoxynol, digitonin, and tween.

A method of forming the piezoelectric composite layer of the fifth operation may include one or more of spin coating, a casting process, and spraying.

A method of performing the silane treatment on the surface of the porous piezoelectric composite layer of the seventh operation may include at least one of immersion in the silane coupling agent and spin coating of the silane coupling agent.

The first electrode or the second electrode of the seventh operation may be a conductor including one or more of gold, silver, copper, platinum, chromium, aluminum, titanium, and nickel.

A method of manufacturing the first electrode or the second electrode of the seventh operation may include one or more of thermal evaporation, electron beam evaporation, sputtering, chemical vapor deposition, epitaxy, electrospinning deposition, inkjet printing, spin coating, and spray coating.

The first electrode and the second electrode of the eighth operation may be connected to a detection circuit through a wiring or a via-hole.

The first and second electrodes may achieve an interdigitated-electrode structure in which the first electrode and the second electrode are disposed on an upper surface of the porous piezoelectric composite layer and interdigitated with each other, or an electrode-insulator-electrode structure in which the first electrode is disposed on the upper surface of a substrate and the second electrode is disposed on a lower surface of the substrate.

The device for detecting low-pressure of the eighth operation may include an array in which unit devices are connected in series in parallel or rows in parallel with each other, or an array in which unit devices are connected in series in parallel or rows in parallel with each other on one substrate.

The device for detecting low-pressure of the eighth operation may include an array in which unit devices are stacked and connected in series with each other or arranged in rows.

Other features and aspects will be apparent from the following detailed description, the drawings, and the claims.

### BRIEF DESCRIPTION OF THE DRAWINGS

FIG. 1 is an operation diagram of a manufacturing method of a device for detecting low-pressure according to an embodiment of the present disclosure.

FIGS. 2A and 2B are schematic diagrams schematically showing a method for obtaining a silane-treated piezoelectric nanoparticle.

FIGS. 3A and 3B are schematic diagrams schematically showing a method for obtaining a polymer mixture.

FIGS. 4A and 4B are schematic diagrams schematically showing a method for obtaining a porous piezoelectric composite layer.

FIGS. 5A and 5B are schematic diagrams schematically showing a method for activating a piezoelectric property.

FIG. 6A is a perspective view of a device for detecting low-pressure according to a first embodiment of the present disclosure, and FIG. 6B is a perspective view of a device for detecting low-pressure according to a second embodiment of the present disclosure.

FIG. 7A is a cross-sectional view taken along AA′ of FIG. 6A, and FIG. 7B is a cross-sectional view taken along AA′ of FIG. 6B.

FIG. 8A is a cross-sectional view taken along BB′ of FIG. 6A, and FIG. 8B is a cross-sectional view taken along BB′ of FIG. 6B.

FIG. 9A is an exploded perspective view of FIG. 6A, and FIG. 9B is an exploded perspective view of FIG. 6B.

FIG. 10A is a top view of FIG. 6A, and FIG. 10B is a top view of FIG. 6B.

FIG. 11A is a view showing an array in which unit devices of the device for detecting low-pressure of the first embodiment are connected in series in parallel with each other, and FIG. 11B is a view showing an array in which unit devices of the device for detecting low-pressure of the second embodiment are connected in series in parallel with each other.

FIG. 12A is a view showing an array in which the unit devices of the device for detecting low-pressure of the first embodiment are connected in series in parallel with each other on one substrate, and FIG. 12B is a view showing an array in which the unit devices of the device for detecting low-pressure of the second embodiment are connected in series in parallel with each other on one substrate.

FIG. 13A is a view showing an array of the unit devices of the device for detecting low-pressure of the first embodiment are connected in rows in parallel with each other, and FIG. 13B is a view showing an array in which the unit devices of the device for detecting low-pressure of the second embodiment are connected in rows in parallel with each other.

FIG. 14A is a view showing an array in which the unit devices of the device for detecting low-pressure of the first embodiment are connected in rows in parallel with each other on one substrate, and FIG. 14B is a view showing an array in which the unit devices of the device for detecting low-pressure of the second embodiment are connected in rows in parallel with each other on one substrate.

FIG. 15A is a view showing an array in which the unit devices of the device for detecting low-pressure of the first embodiment are stacked and connected in series in parallel with each other, and FIG. 15B is a view showing an array in which the unit devices of the device for detecting low-pressure of the second embodiment are stacked and connected in series in parallel with each other.

FIG. 16A is a view showing an array in which the unit devices of the device for detecting low-pressure of the first embodiment are stacked and connected in rows in parallel with each other, and FIG. 16B is a view showing an array in which the unit devices of the device for detecting low-pressure of the second embodiment are stacked and connected in rows in parallel with each other.

FIGS. 17A to 19B are schematic diagrams showing a principle of detecting an electrical signal based on pressure applied to the device for detecting low-pressure.

### DETAILED DESCRIPTION OF EMBODIMENTS

Hereinafter, the present disclosure is described with reference to the accompanying drawings.

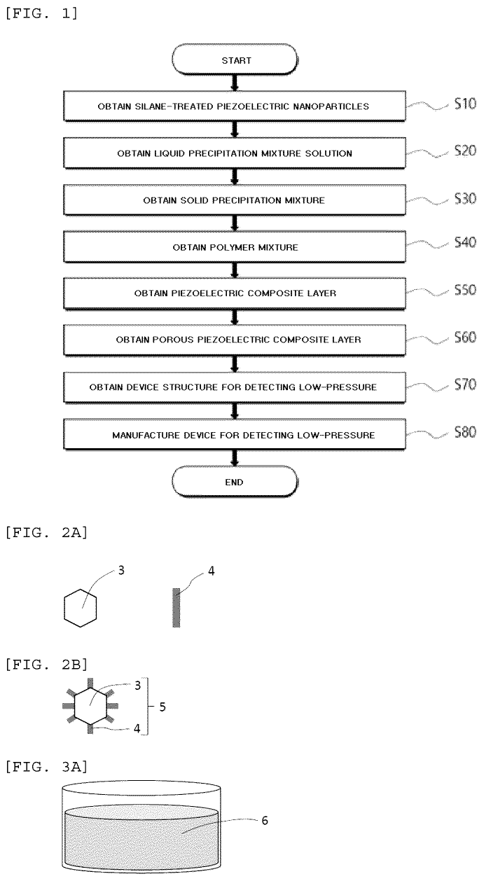

FIG. 1 is an operation diagram of a manufacturing method of a device for detecting low-pressure according to an embodiment of the present disclosure. As shown in FIG. 1, the method may include: a first operation (S10) of obtaining a silane-treated piezoelectric nanoparticle; a second operation (S20) of obtaining a liquid precipitation mixture solution by mixing a precipitated particle solute and a liquid solvent with a polymer; a third operation (S30) of obtaining a solid precipitation mixture in which a solidified precipitated particle is mixed with the polymer from the liquid precipitation mixture solution; a fourth operation (S40) of obtaining a polymer mixture by mixing a nonionic surfactant with the solid precipitation mixture; a fifth operation (S50) of obtaining a piezoelectric composite layer by mixing the silane-treated piezoelectric nanoparticle with the polymer mixture; a sixth operation (S60) of obtaining a porous piezoelectric composite layer having pores by removing the solidified precipitated particle from the piezoelectric composite layer; a seventh operation (S70) of performing silane surface treatment and plasma surface treatment on the porous piezoelectric composite layer, and manufacturing a first electrode and a second electrode on a surface of the porous piezoelectric composite layer on which the silane surface treatment and the plasma surface treatment are performed; and an eighth operation (S80) of activating a piezoelectric property by connecting a detection circuit to the first electrode and the second electrode and applying a direct current (DC) electric field thereto.

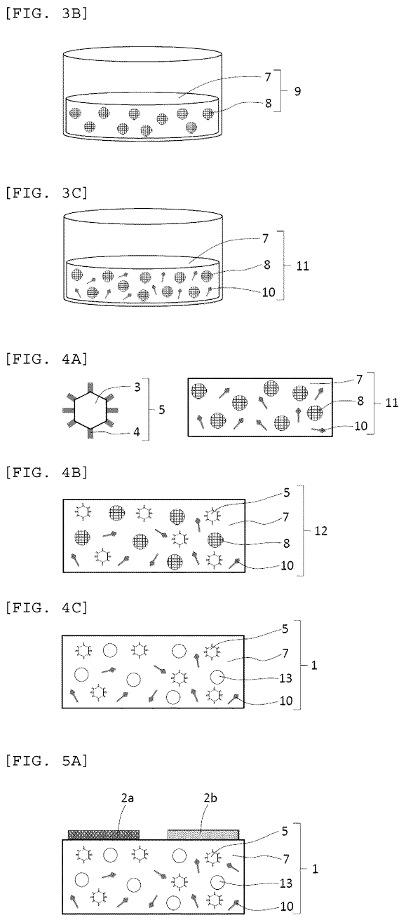

FIGS. 2A and 2B are schematic diagrams schematically showing a method for obtaining a silane-treated piezoelectric nanoparticle. As shown in FIG. 2A, a piezoelectric nanoparticle 3 and a silane coupling agent 4 hydrolyzed by the liquid solvent may be prepared, respectively, and as shown in FIG. 2B, a silane-treated piezoelectric nanoparticle 5 may be obtained through a condensation reaction between the piezoelectric nanoparticle 3 and the hydrolyzed silane coupling agent 4.

The piezoelectric nanoparticle 3 may include one or more of lead zirconate titanate (PZT), barium titanate (BaTiO₃), lead titanate (PbTiO₃), titanium dioxide (TiO₂), strontium titanate (SrTiO₃), and zirconium dioxide (ZrO₂), each of which has a perovskite structure. The liquid solvent may include one or more of water, ethanol, methanol, acetone, and toluene. The silane coupling agent may include one or more of 3-glycidoxypropyltrimethoxysilane (GPTMS), 3-mercaptopropyltrimethoxysilane (MPTMS), 3-aminopropyltriethoxysilane (APTES), and bis3-triethoxysilylpropyltetrasulfide (TESPT). A method of the silane treatment may include one or more of ultrasonic vibration, agitation, soaking, and shaking.

FIGS. 3A and 3B are schematic diagrams schematically showing a method for obtaining the polymer mixture. As shown in FIG. 3A, a liquid precipitation mixture solution 6 may be obtained by mixing the precipitated particle solute and the liquid solvent with the polymer; as shown in FIG. 3B, the liquid precipitation mixture solution 6 may be heated to vaporize the liquid solvent to obtain the solid precipitation mixture 9 in which a solidified precipitated particle 8 is mixed with a polymer 7; and as shown in FIG. 3C, the polymer mixture 9 may be obtained by mixing a nonionic surfactant 10 with the solid precipitation mixture 9.

The polymer 7 may include one or more of polydimethylsiloane (PDMS), polymethylmethacrylate (PMMA), negative epoxy based photoresist (SU-8), and polyurethane leather (PU). The precipitated particle solute may include one or more of citric acid, sugar, salt, and baking soda. The nonionic surfactant may include one or more of triton, nonoxynol, digitonin, and tween.

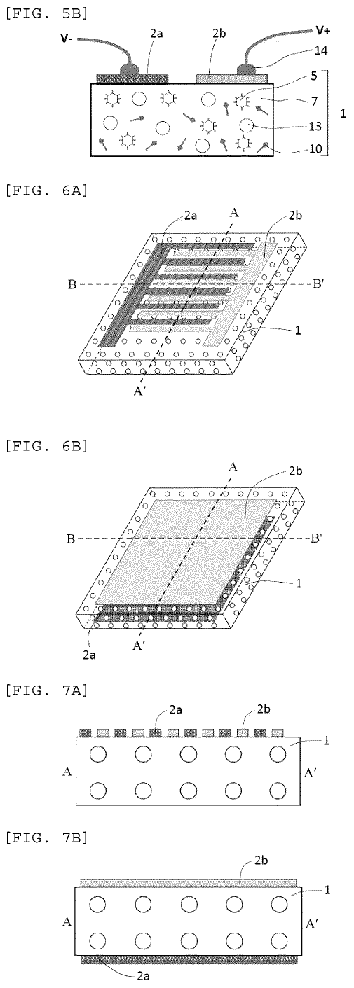

FIGS. 4A and 4B are schematic diagrams schematically showing a method for obtaining the porous piezoelectric composite layer. As shown in FIG. 4A, the silane-treated piezoelectric nanoparticle 5 and a polymer mixture 11 may be prepared; as shown in FIG. 4B, the cured piezoelectric composite layer may be obtained by mixing the silane-treated piezoelectric nanoparticle 5 with the polymer mixture 11 and curing the same through heat treatment; and as shown in FIG. 4C, a porous piezoelectric composite layer 1 having pores 13 may be obtained by removing the solidified precipitated particle 8 in a cured piezoelectric composite layer 12 by using the liquid solvent.

A method of forming the piezoelectric composite layer 13 may include one or more of spin coating, a casting process, and spraying.

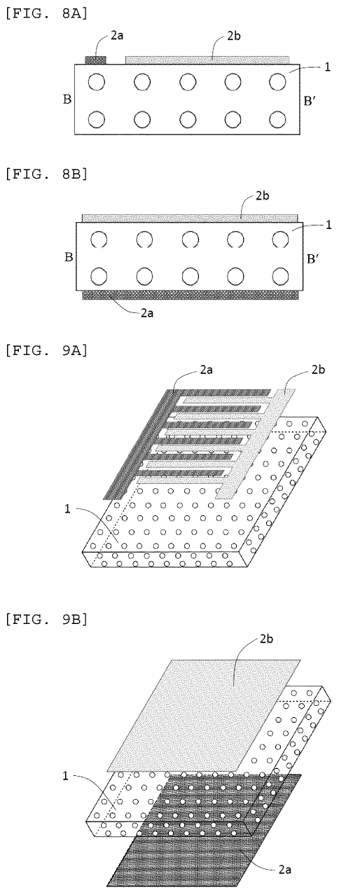

FIGS. 5A and 5B are schematic diagrams schematically showing a method for activating the piezoelectric property. As shown in FIG. 5A, a coating layer may be formed by sequentially performing the silane treatment and the plasma treatment on a surface of a porous piezoelectric composite layer 1, and a first electrode 2a and a second electrode 2b may be formed on the coating layer to obtain a device structure for detecting low-pressure; and as shown in FIG. 5B, in the device structure for detecting low-pressure, the first electrode 2a and the second electrode 2b may be connected to a detection circuit 14, and the DC electric field may be applied thereto to activate the piezoelectric property, thereby manufacturing the device for detecting low-pressure.

A method of performing the silane treatment on the surface of the porous piezoelectric composite layer 1 may include at least one of immersion in the silane coupling agent and spin coating of the silane coupling agent. A method of manufacturing the first electrode 2a or the second electrode 2b may include one or more of thermal evaporation, electron beam evaporation, sputtering, chemical vapor deposition, epitaxy, electrospinning deposition, inkjet printing, spin coating, and spray coating. The first electrode 2a or the second electrode 2b may be a conductor including one or more of gold, silver, copper, platinum, chromium, aluminum, titanium, and nickel.

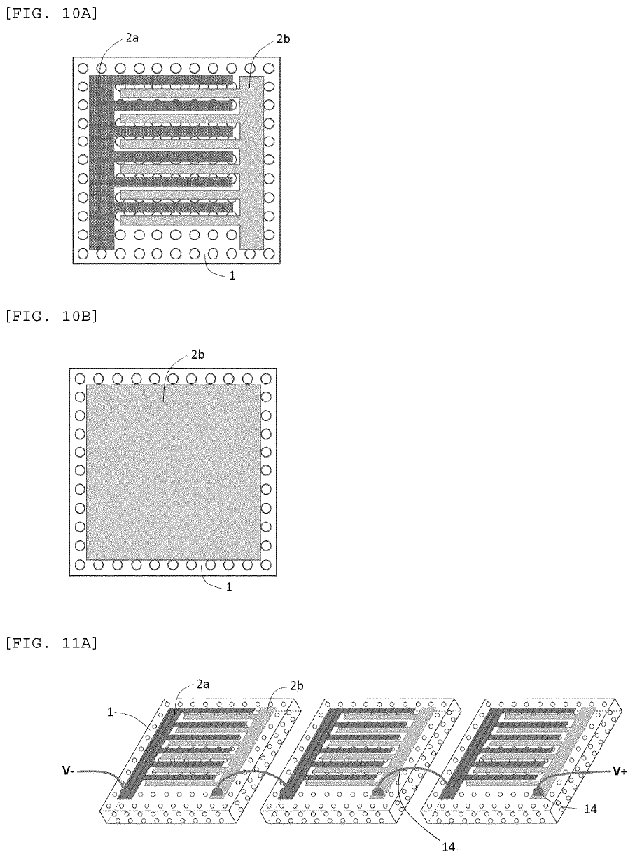

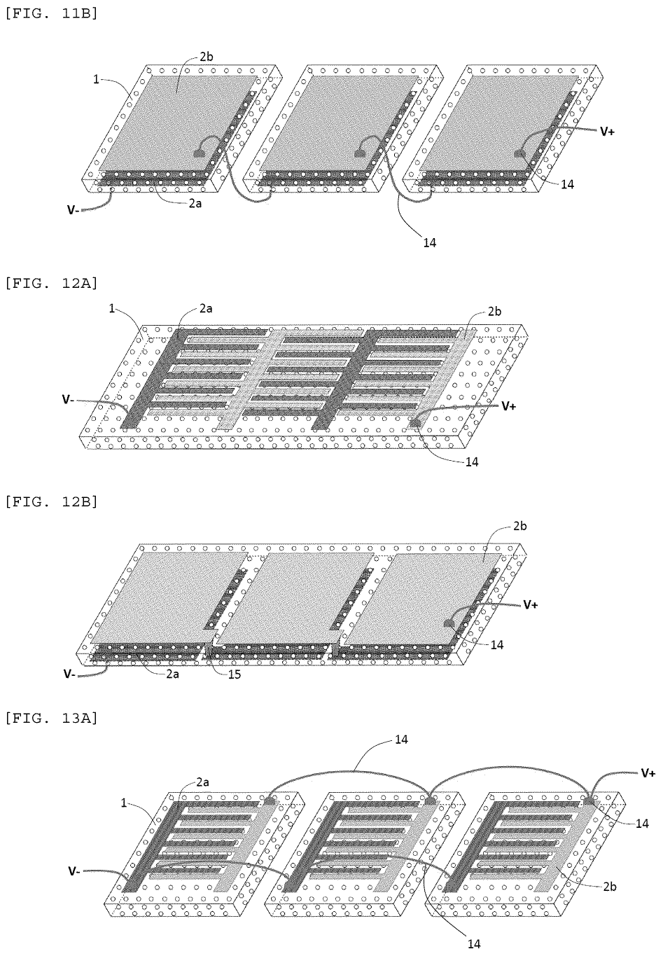

FIG. 6A is a perspective view of a device for detecting low-pressure according to a first embodiment of the present disclosure, and FIG. 6B is a perspective view of a device for detecting low-pressure according to a second embodiment of the present disclosure. FIG. 7A is a cross-sectional view taken along AA′ of FIG. 6A, and FIG. 7B is a cross-sectional view taken along AA′ of FIG. 6B. FIG. 8A is a cross-sectional view taken along BB′ of FIG. 6A, and FIG. 8B is a cross-sectional view taken along BB′ of FIG. 6B. FIG. 9A is an exploded perspective view of FIG. 6A, and FIG. 9B is an exploded perspective view of FIG. 6B. FIG. 10A is a top view of FIG. 6A, and FIG. 10B is a top view of FIG. 6B. In the device for detecting low-pressure according to the first embodiment, the first and second electrodes 2a and 2b may achieve an interdigitated-electrode structure in which the first electrode 2a and the second electrode 2b are disposed on an upper surface of the porous piezoelectric composite layer 1, and disposed on both sides thereof to be interdigitated with each other. Alternatively, in the device for detecting low-pressure according to the second embodiment, the first and second electrodes 2a and 2b may have an electrode-insulator-electrode structure in which the first electrode 2a and the second electrode 2b are respectively disposed on the upper surface and lower surface of the porous piezoelectric composite layer 1.

FIG. 11A is a view showing an array in which unit devices of the device for detecting low-pressure of the first embodiment are connected in series in parallel with each other, and FIG. 11B is a view showing an array in which unit devices of the device for detecting low-pressure of the second embodiment are connected in series in parallel with each other. As shown in the drawings, the device for detecting low-pressure may have a structure in which the plurality of unit devices are arrayed parallel to each other and connected in series with each other. Here, the first electrode of one of two adjacent unit devices and the second electrode of the other may be connected with each other through a wiring 14. An electrical signal may then be received through the wiring 14 connected to the respective electrodes positioned at two ends of the two adjacent unit devices.

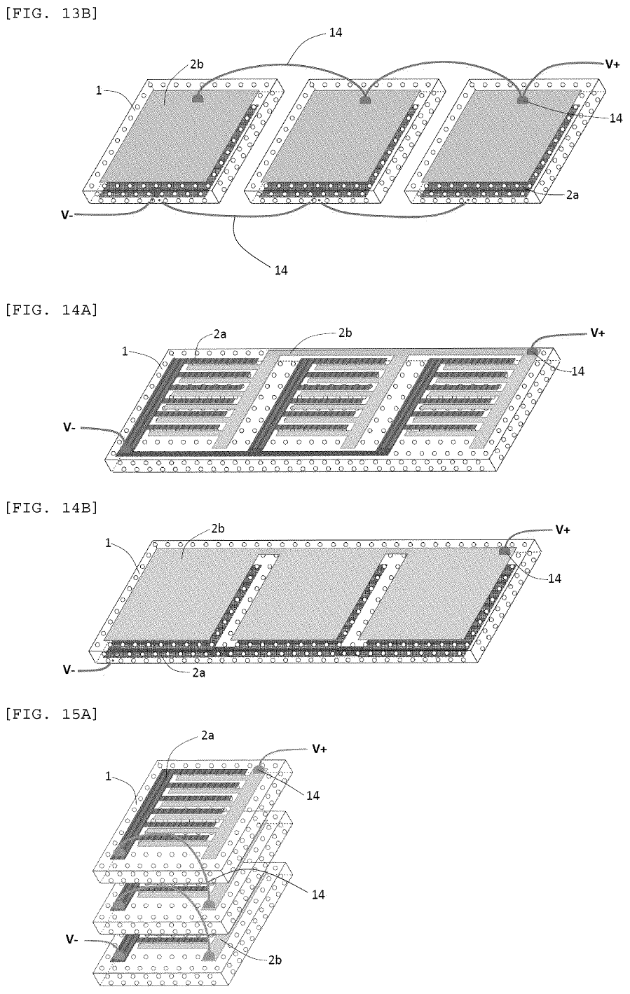

FIG. 12A is a view showing an array in which the unit devices of the device for detecting low-pressure of the first embodiment are connected in series in parallel with each other on one substrate, and FIG. 12B is a view showing an array in which the unit devices of the device for detecting low-pressure of the second embodiment are connected in series in parallel with each other on one substrate. As shown in the drawings, the device for detecting low-pressure may have a structure in which the plurality of unit devices are connected in series with each other on one substrate 1, that is, the porous piezoelectric composite layer 1 described above. This structure may be configured by manufacturing the plurality of first electrodes 2a and the plurality of second electrodes 2b on the porous piezoelectric composite layer. Here, when the unit devices are connected in series with each other, the first electrode of one of the two adjacent unit devices and the second electrode of the other may serve as one electrode. Alternatively, when the unit devices are connected in series with each other, the first electrode of one of the two adjacent unit devices and the second electrode of the other may be connected with each other through a via-hole wiring 16, and to this end, a substrate 1 may have a through hole. The electrical signal may then be received through the wiring 14 connected to the respective electrodes positioned at the two ends of two adjacent unit devices.

FIG. 13A is a view showing an array of the unit devices of the device for detecting low-pressure of the first embodiment are connected in rows in parallel with each other, and FIG. 13B is a view showing an array in which the unit devices of the device for detecting low-pressure of the second embodiment are connected in rows in parallel with each other. As shown in the drawings, the device for detecting low-pressure may have a structure in which the plurality of unit devices are arrayed parallel to each other and arranged in rows. Here, the first electrode of one of the two adjacent unit devices and the first electrode of the other, and the second electrode of one of the two adjacent unit devices and the second electrode of the other may respectively be connected with each other through the wiring 14. The electrical signal may then be received through the wiring 14 connected to the respective electrodes positioned at the two ends of the two adjacent unit devices.

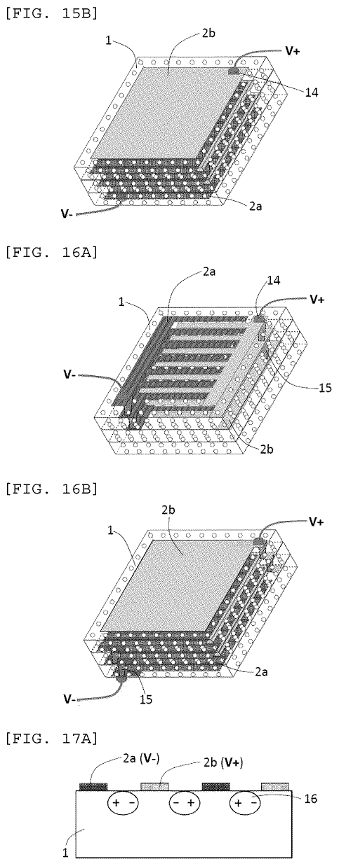

FIG. 14A is a view showing an array in which the unit devices of the device for detecting low-pressure of the first embodiment are connected in rows in parallel with each other on one substrate, and FIG. 14B is a view showing an array in which the unit devices of the device for detecting low-pressure of the second embodiment are connected in rows in parallel with each other on one substrate. As shown in the drawings, the device for detecting low-pressure may have a structure in which the plurality of unit devices are arranged in rows on the one substrate 1, that is, the porous piezoelectric composite layer 1 described above. This structure may be configured by manufacturing the plurality of first electrodes 2a and the plurality of second electrodes 2b on the porous piezoelectric composite layer. Here, when the unit devices are arranged in rows, the first electrode of one of the two adjacent unit devices and the first electrode of the other, and the second electrode of one of the two adjacent unit devices and the second electrode of the other may respectively extend to respectively be connected with each other. Alternatively, when the unit devices are arranged in rows, the first electrode of one of the two adjacent unit devices and the first electrode of the other, and the second electrode of one of the two adjacent unit devices and the second electrode of the other may respectively extend to respectively be connected with each other. The electrical signal may then be received through the wiring 14 connected to the respective electrodes positioned at the two ends of the two adjacent unit devices.

FIG. 15A is a view showing an array in which the unit devices of the device for detecting low-pressure of the first embodiment are stacked and connected in series in parallel with each other, and FIG. 15B is a view showing an array in which the unit devices of the device for detecting low-pressure of the second embodiment are stacked and connected in series in parallel with each other. As shown in the drawings, the device for detecting low-pressure may have a structure in which the plurality of unit devices are stacked and connected in series with each other. Here, the first electrode of one of the two adjacent unit devices and the second electrode of the other may be connected with each other through the wiring 14. The electrical signal may then be received through the wiring 14 connected to the respective electrodes positioned at the two ends of the two adjacent unit devices.

FIG. 16A is a view showing an array in which the unit devices of the device for detecting low-pressure of the first embodiment are stacked and connected in rows in parallel with each other, and FIG. 16B is a view showing an array in which the unit devices of the device for detecting low-pressure of the second embodiment are stacked and connected in rows in parallel with each other. As shown in the drawings, the device for detecting low-pressure may have a structure in which the plurality of unit devices are stacked and arranged in rows. Here, the first electrode of one of the two adjacent unit devices and the first electrode of the other, and the second electrode of one of the two adjacent unit devices and the second electrode of the other may respectively be connected with each other through the via-hole wiring 16, and to this end, the substrate 1 may have the through hole. The electrical signal may then be received through the wiring 14 connected to the respective electrodes positioned at the two ends of the two adjacent unit devices.

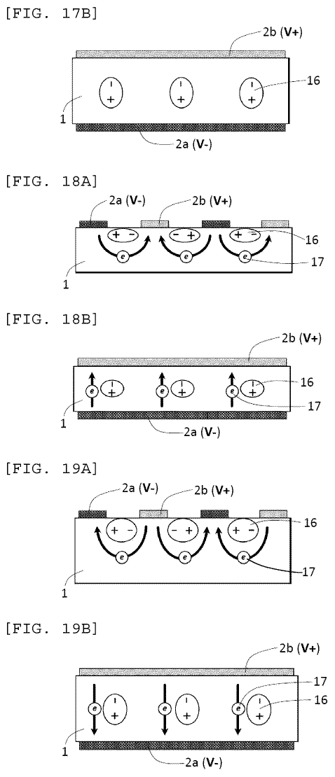

FIGS. 17A to 19B are schematic diagrams showing a principle of detecting the electrical signal based on pressure applied to the device for detecting low-pressure. As shown in FIGS. 17A and 17B, a dipole 15 having both a positive electrode and a negative electrode may be positioned in the porous piezoelectric composite layer 1 of the device for detecting low-pressure, and the positive electrode of the dipole may be aligned to face the first electrode 2a and the negative electrode may be aligned to face the second electrode 2b. As shown in FIGS. 18A and 18B, when pressure is applied to the device for detecting low-pressure, the dipole 17 in the porous piezoelectric composite layer 1 may be compressed to cause a polarization phenomenon, and electrons 18 may thus move from the first electrode 2a to the second electrode 2b. Here, the electrical signal based on the applied pressure may be detected from the first electrode 2a and the second electrode 2b. As shown in FIGS. 19A and 19B, when the pressure applied to the device for detecting low-pressure is relieved, the dipole 17 in the porous piezoelectric composite layer 1 may be restored to an initial state, and the electrons 18 may thus move from the second electrode 2b to the first electrode 2a. Here, the electrical signal based on the pressure relief may be detected from the first electrode 2a and the second electrode 2b.

Hereinafter, a device for detecting low-pressure according to another embodiment of the present disclosure is described with reference to FIGS. 2A to 19B again.

The device for detecting low-pressure in the present disclosure may be manufactured by the above-described manufacturing method of a device for detecting low-pressure.

The device for detecting low-pressure may include a substrate 1 and a first electrode 2a and a second electrode 2b positioned on a surface of the substrate. The first electrode and the second electrode may each be a thin film electrode, which is made of a thin metal layer.

Here, the substrate 1 may have a porous structure in which piezoelectric nanoparticles are uniformly distributed. That is, the substrate 1 may correspond to the above-mentioned porous piezoelectric composite layer 1. In addition, a piezoelectric nanoparticle 5 in the substrate may be a silane-treated piezoelectric nanoparticle, which is formed through the condensation reaction between the piezoelectric nanoparticle 3 and the hydrolyzed silane coupling agent 4 as described above.

In the porous piezoelectric composite layer 1, the silane-treated piezoelectric nanoparticles and nonionic surfactant-distributed polymers may be mixed with each other to prevent the aggregation and precipitation of the piezoelectric nanoparticles. Accordingly, the piezoelectric nanoparticles in the matrix have high dispersibility, and thus are uniformly distributed. This method may solve a conventional problem of the aggregation of piezoelectric nanoparticles.

In addition, the porous structure of the porous piezoelectric composite layer 1 may be manufactured by a spin coating process by obtaining a solid precipitation mixture in which solidified precipitated particles are mixed with the polymer and selectively dissolving the solidified precipitated particles through a liquid solvent. As such, the substrate may have the porous structure to thus improve reactivity of the piezoelectric nanoparticle, and simultaneously improve a property of the substrate itself such as flexibility of the substrate. The substrate 1 may have a predetermined level of viscosity, and thus be adhered to a skin or the like without a separate adhesive.

In addition, although not shown, a coating layer may be formed on the surface of the substrate 1, and the first electrode 2a and the second electrode 2b may be disposed on the coating layer. The coating layer may be formed by sequentially performing silane treatment and plasma treatment on the surface of the porous piezoelectric composite layer 1. Here, the treatment may use a silane coupling agent of 3-mercaptopropyltrimethoxysilane (MPTMS), and oxygen plasma. In this way, by being formed on the coating layer, a thin film electrode with high adhesion and no cracks/wrinkles may be manufactured on the surface of the substrate.

In the device for detecting low-pressure of the present disclosure, the substrate 1 may have a thickness of 10 to 200 μm, and each of the first electrode 2a and the second electrode 2b may have a thickness of 10 to 200 nm. This thickness is a very small scale compared to a conventional device, and may correspond to an ultra-small and ultra-thin device.

As described above, the first electrode 2a and the second electrode 2b may each be a conductor including one or more of gold, silver, copper, platinum, chromium, aluminum, titanium, and nickel, and in more detail, the first electrode 2a and the second electrode 2b may each have a structure in which different types of metal layers, for example, gold-chromium, are stacked. Chromium may provide improved adhesion, and have a scale of about 1/200 to 1/50 of a thickness of gold.

Referring again to FIGS. 11A to 16B, the first and second electrodes 2a and 2b may achieve an interdigitated-electrode structure in which the electrodes are respectively disposed on an upper surface of the substrate 1 and interdigitated with each other, or an electrode-insulator-electrode structure in which the first electrode 2a is disposed on the upper surface of the substrate 1 and the second electrode 2b is disposed on a lower surface of the substrate 1.

In addition, the device for detecting low-pressure according to the present disclosure may include a plurality of unit devices, and the unit devices may be arrayed parallel to each other and connected in series with each other or arranged in rows, or stacked-arrayed and connected in series with each other or arranged in rows. Here, the unit devices may be configured by manufacturing the plurality of first electrodes and the plurality of second electrodes on one substrate. This configuration is the same as the description provided above, and a detailed description thereof is omitted.

As described above, according to the present disclosure, the piezoelectric nanoparticles may be uniformly distributed in the substrate through the predetermined chemical treatment to improve the reactivity, the porous structure of the substrate may improve the flexibility of the substrate, and the electrode thin film formed on the coating layer to improve the adhesion and simultaneously to prevent cracks and wrinkles.

As set forth above, according to the present disclosure, it is possible to manufacture the piezoelectric composite layer having the high dispersibility of the piezoelectric nanoparticles in the matrix by mixing the silane-treated piezoelectric nanoparticle and the nonionic surfactant-distributed polymer to prevent the aggregation and precipitation of the piezoelectric nanoparticles.

Further, the piezoelectric composite layer may have the porous structure by obtaining the solid precipitation mixture in which the solidified precipitated particle is mixed with the polymer, and selectively dissolving the solidified precipitated particle by using the liquid solvent.

Furthermore, the thin film electrode having the high adhesion and no cracks/wrinkles may be manufactured on the surface of the porous piezoelectric composite layer by sequentially performing the silane treatment and the plasma treatment on the surface of the porous piezoelectric composite layer to thus form the coating layer.

The embodiments of the present disclosure have been described hereinabove with reference to the accompanying drawings. However, it is to be understood by those skilled in the art to which the present disclosure pertains that various modifications and alterations may be made without departing from the technical spirit or essential feature of the present disclosure. Therefore, it is to be understood that the embodiments described above are illustrative rather than being restrictive in all aspects.

What is claimed is:

1. A device for detecting low-pressure comprising a porous piezoelectric composite layer and first and second electrodes,
wherein the first and second electrodes achieve an interdigitated-electrode structure in which the first electrode and the second electrode are disposed on an upper surface of the porous piezoelectric composite layer and interdigitated with each other, or an electrode-insulator-electrode structure in which the first electrode is disposed on the upper surface of the porous piezoelectric composite layer and the second electrode is disposed on a lower surface of the porous piezoelectric composite layer.

2. A manufacturing method of the device for detecting low-pressure of claim 1, the method comprising:
a first operation of obtaining a silane-treated piezoelectric nanoparticle by mixing a piezoelectric nanoparticle and a silane coupling agent hydrolyzed by a liquid solvent and performing silane treatment thereon;
a second operation of obtaining a liquid precipitation mixture solution by mixing a precipitated particle solute and a liquid solvent with a polymer;
a third operation of obtaining a solid precipitation mixture in which a solidified precipitated particle is mixed with the polymer by vaporizing the liquid solvent by heating the liquid precipitation mixture solution of the second operation;
a fourth operation of obtaining a polymer mixture by mixing a nonionic surfactant with the solid precipitation mixture of the third operation;
a fifth operation of obtaining a cured piezoelectric composite layer by mixing the silane-treated piezoelectric nanoparticle of the first operation with the polymer mixture of the fourth operation and curing the same through heat treatment;
a sixth operation of obtaining a porous piezoelectric composite layer by removing the solidified precipitated particle from the cured piezoelectric composite layer of the fifth operation by using the liquid solvent;
a seventh operation of forming a coating layer by sequentially performing silane treatment and plasma treatment on a surface of the porous piezoelectric composite layer of the sixth operation, and manufacturing a first electrode and a second electrode on the coating layer; and
an eighth operation of activating a piezoelectric property by applying a direct current electric field to the first electrode and the second electrode of the seventh operation.

3. The method of claim 2, wherein the piezoelectric nanoparticle of the first operation includes one or more of lead zirconate titanate (PZT), barium titanate (BaTiO₃), lead titanate (PbTiO₃), titanium dioxide (TiO₂), strontium titanate (SrTiO₃), and zirconium dioxide (ZrO₂), each of which has a perovskite structure.

4. The method of claim 2, wherein the liquid solvent of the first, second, third or sixth operation includes one or more of water, ethanol, methanol, acetone, and toluene.

5. The method of claim 2, wherein the silane coupling agent of the first operation includes one or more of 3-glycidoxypropyltrimethoxysilane (GPTMS), 3-mercaptopropyltrimethoxysilane (MP TMS), 3-aminopropyltriethoxysilane (APTES), and bis3-triethoxysilylpropyltetrasulfide (TESPT).

6. The method of claim 2, wherein a method of the silane treatment of the first operation includes one or more of ultrasonic vibration, agitation, soaking, and shaking.

7. The method of claim 2, wherein the polymer of the second operation includes one or more of polydimethylsiloane (PDMS), polymethylmethacrylate (PMMA), negative epoxy based photoresist (SU-8), and polyurethane leather (PU).

8. The method of claim 2, wherein the precipitated particle solute of the second operation includes one or more of citric acid, sugar, salt, and baking soda.

9. The method of claim 2, wherein the nonionic surfactant of the fourth operation includes one or more of triton, nonoxynol, digitonin, and tween.

10. The method of claim 2, wherein a method of forming the piezoelectric composite layer of the fifth operation includes one or more of spin coating, a casting process, and spraying.

11. The method of claim 2, wherein a method of performing the silane treatment on the surface of the porous piezoelectric composite layer of the seventh operation includes at least one of immersion in the silane coupling agent and spin coating of the silane coupling agent.

12. The method of claim 2, wherein the first electrode or the second electrode of the seventh operation is a conductor including one or more of gold, silver, copper, platinum, chromium, aluminum, titanium, and nickel.

13. The method of claim 2, wherein a method of manufacturing the first electrode or the second electrode of the seventh operation includes one or more of thermal evaporation, electron beam evaporation, sputtering, chemical vapor deposition, epitaxy, electrospinning deposition, inkjet printing, spin coating, and spray coating.

14. The method of claim 2, wherein the first electrode and the second electrode of the eighth operation are connected to a detection circuit through a wiring or a via-hole.

15. The method of claim 2, wherein the device for detecting low-pressure of the eighth operation includes an array in which unit devices are connected in series in parallel or rows in parallel with each other, or an array in which unit devices are connected in series in parallel or rows in parallel with each other on one substrate.

16. The method of claim 2, wherein the device for detecting low-pressure of the eighth operation includes an array in which unit devices are stacked and connected in series with each other or arranged in rows.
